(19) United States
(12) Patent Application Publication
(10) Pub. No.: US 2019/0006342 A1
(43) Pub. Date: Jan. 3, 2019

(54) RIGID ADHESIVE PACKAGE-ON-PACKAGE SEMICONDUCTORS

(71) Applicant: Intel Corporation, Santa Clara, CA (US)

(72) Inventors: OMKAR KARHADE, Chandler, AZ (US); NITIN DESHPANDE, Chandler, AZ (US)

(73) Assignee: Intel Corporation, Santa Clara, CA (US)

(21) Appl. No.: 15/639,667

(22) Filed: Jun. 30, 2017

(51) Int. Cl. H01L 25/00; H01L 25/10; H01L 21/48; H01L 21/78; H01L 25/18

(52) U.S. Cl. CPC H01L 25/50; H01L 23/3731; H01L 21/4882; H01L 21/481; H01L 21/78; H01L 25/18; H01L 2225/1023; H01L 2225/1058; H01L 2225/1094; H01L 2225/1041; H01L 2225/0651; H01L 2225/06513; H01L 2225/06517; H01L 2225/06589; H01L 25/105

(57) ABSTRACT

Systems and methods for improving heat distribution and heat removal efficiency in PoP semiconductor packages are provided. A PoP semiconductor package includes a first semiconductor package that is physically, communicably, and conductively coupled to a stacked second semiconductor package. A thermal structure is physically and thermally coupled to the upper surface of the first semiconductor package and to the lower surface of the second semiconductor package. The thermal structure has opposed first and second surfaces and includes a first adhesive layer disposed across the first surface and a second adhesive layer disposed across the second surface. The first adhesive layer physically and thermally couples the thermal structure to the lower surface of the second semiconductor package. The second adhesive layer physically and thermally couples the thermal structure to the upper surface of the first semiconductor package.

### TECHNICAL FIELD

The present disclosure relates to semiconductor fabrication and the transfer of thermal energy within a package-on-package semiconductor package.

### BACKGROUND

Package-on-package (PoP) is an integrated circuit packaging technology in which a number of ball grid array (BGA) packages are arranged vertically. PoP packaging beneficially reduces the board area occupied by individually semiconductor packages. PoP packaging also minimizes track length between components that frequently interoperate. Minimizing track length provides more rapid signal propagation, reduced noise, and reduced channel cross-talk. In assembly, PoP packaging permits the testing of individual components prior to stacking rather than after stacking (e.g., chip stacking), reducing rework since only known good components are used in the PoP package.

In a typical PoP integrated circuit a memory package is stacked with a logic package, such as a system-on-a-chip (SoC). Frequently, the stacked packages are stacked and then physically and conductively coupled via reforming. Since most semiconductor packages create heat when operating, heat produced by the semiconductor packages in the stack must be dissipated through a relatively small area. The reduced heat transfer within a PoP package leads to the formation of hot spots within the stack and, ultimately, to premature failure of the PoP package.

### BRIEF DESCRIPTION OF THE DRAWINGS

Features and advantages of various embodiments of the claimed subject matter will become apparent as the following Detailed Description proceeds, and upon reference to the Drawings, wherein like numerals designate like parts, and in which:

FIG. 1 is a cross-sectional elevation of an illustrative package-on-package (PoP) semiconductor package in which a first semiconductor package and a second semiconductor package are stacked forming a gap between the upper surface of the first semiconductor package and the lower surface of the second semiconductor package and in which a thermal structure that includes a first adhesive layer and a second adhesive layer attached to a rigid substrate thermally conductively couples the first semiconductor package to the second semiconductor package, in accordance with at least one embodiment described herein;

FIG. 2A is a cross-sectional elevation that depicts a non-exclusive, illustrative, fabrication method of a thermal structure, in accordance with at least one embodiment described herein;

FIG. 2B is a cross-sectional elevation that depicts a non-exclusive, illustrative, fabrication method of a thermal structure after back grinding the substrate, in accordance with at least one embodiment described herein;

FIG. 2C is a cross-sectional elevation that depicts a non-exclusive, illustrative, fabrication method of a thermal structure that includes the removal (i.e., peeling) of the back grinding tape from the first adhesive layer, in accordance with at least one embodiment described herein;

FIG. 2D is a cross-sectional elevation that depicts a non-exclusive, illustrative, fabrication method of a thermal structure that includes the deposition of the second adhesive layer on the second surface of the thinned substrate, in accordance with at least one embodiment described herein;

FIG. 2E is a cross-sectional elevation that depicts a non-exclusive, illustrative, fabrication method of a thermal structure after the thermal structure has been singulated in preparation for deposition or placement between the first semiconductor package and the second semiconductor package, in accordance with at least one embodiment described herein;

FIG. 2F is a cross-sectional elevation that depicts a non-exclusive, illustrative, fabrication method of a thermal structure coupled, by the first adhesive layer, to a lower surface of a second semiconductor package, in accordance with at least one embodiment described herein;

FIG. 2G is a cross-sectional elevation that depicts a non-exclusive, illustrative, fabrication method of a thermal structure 130 that includes the removal (i.e., peeling) of the dicing tape from the second adhesive layer, in accordance with at least one embodiment described herein;

FIG. 2H is a cross-sectional elevation that depicts a non-exclusive, illustrative, fabrication method of a PoP semiconductor package that includes a thermal structure physically and thermally coupling the upper surface of the first semiconductor package with the lower surface of the second semiconductor package, in accordance with at least one embodiment described herein;

FIG. 3 is a high-level flow diagram of an illustrative method of fabricating a PoP semiconductor package that includes a thermal structure to physically and thermally couple a first semiconductor package to a second semiconductor package, in accordance with at least one embodiment described herein; and

FIG. 4 is a high-level flow diagram of an illustrative method of fabricating a PoP semiconductor package that includes a thermal structure to physically and thermally couple a first semiconductor package to a second semiconductor package, in accordance with at least one embodiment described herein.

Although the following Detailed Description will proceed with reference being made to illustrative embodiments, many alternatives, modifications and variations thereof will be apparent to those skilled in the art.

### DETAILED DESCRIPTION

The systems and methods disclosed herein provide for a package-on-package (PoP) construction using a thermal structure that includes adhesive layers disposed on both sides of a rigid member that physically strengthens and supports the relatively soft, pliable, adhesive layers. The thermal structure may be formed from materials that provide a composite thermal conductivity that exceeds the thermal conductivity of the molding compounds used in the semiconductor packages forming the PoP semiconductor package. The thermal structure may be positioned between two semiconductor packages in a PoP semiconductor package to facilitate the distribution of heat in an x-y direction across the upper surface of the semiconductor package positioned below the thermal structure. The thermal structure may also facilitate the removal of heat in the z-direction by transferring heat generated by the semiconductor package positioned below the thermal structure to the semiconductor package positioned above the thermal structure. Any number of thermal structures may be so positioned within a PoP semiconductor package. For example, in a PoP semiconductor package having three semiconductor packages a thermal structure may be positioned between the lowermost and middle semiconductor packages and between the middle and uppermost semiconductor packages. In some implementations, a thermal structure may be positioned beneath the lowermost semiconductor package to facilitate heat transfer to the substrate on which the semiconductor package is mounted.

The adhesive layers disposed on either side of the thermal structure provide at least two benefits First, the adhesive layers physically couple the semiconductor packages above and below the thermal structure to the thermal structure, improving the physical integrity of the PoP semiconductor package. Second, the adhesive layers thermally couple the semiconductor packages above and below the thermal structure, improving the heat distribution in an x-y direction across the upper surface of the lower semiconductor package and also in a z-direction from the lower semiconductor package to the upper semiconductor package.

When compared to the physical and thermal performance of the disclosed thermal structure, the use of conventional liquid or paste adhesives to both physically and thermally couple semiconductor packages has several drawbacks. First, uniform application of an adhesive to a semiconductor package such that no gaps or voids exist within the cured adhesive is necessary to: ensure uniform heat distribution, avoid generating hotspots, and ensure near uniform heat transfer between semiconductor packages. Second, an over-application of adhesive to ensure adequate coverage leads to extrusion of the adhesive and potentially compromises the integrity of the conductive coupling between the semiconductor packages. Physically and thermally coupling the first semiconductor package and the second semiconductor package using an adhesive film disposed on a rigid substrate addresses these issues.

Die attach films (DAFs) offer consistent thickness and adhesive density, factors that facilitate favorable thermal conduction properties. The uniform thickness and adhesive layer on DAFs minimizes or even eliminates the possibility of voids, bubbles, or other defects in thermal continuity and resultant compromised heat transfer between the lower semiconductor package and the upper semiconductor package in a PoP semiconductor package. The fixed area of DAF applied to a semiconductor package reduces or eliminates the possibility of adhesive extrusion during the semiconductor package stacking process. Furthermore, the use of a rigid substrate provides a supporting structure for the DAF, making the DAF easier to handle and easier to place within the die stack.

Filling the gap between the upper semiconductor package and the lower semiconductor package provides a thermally efficient stack that both: promotes a more even heat distribution across both the upper and lower package; and facilitates a more efficient heat removal from the lowermost semiconductor packages in the stack. Furthermore, the use of DAF disposed on a rigid substrate to physically and thermally couple the upper and lower semiconductor packages permits the use of smaller gaps (e.g., 20 micrometer (μm) to 60 μm) between the upper and lower semiconductor packages, further improving thermal performance within the PoP semiconductor package. Thus, the systems and methods described herein provide a significant advantage over capillary underfill systems which require larger gaps between non-singulated PoP package strips or arrays and which tend to detrimentally deposit the underfill material in the memory bump field disposed about the periphery of the memory package rather than between the semiconductor packages forming the stack. The systems and methods described herein use DAF attached to a rigid substrate to fill the gap between a first (i.e., lower) semiconductor package and the second (i.e., upper) semiconductor package.

Generally, the systems and methods described herein provide greater thermal conductivity in the z-direction than PoP semiconductor packages in which an air gap or similar thermally disruptive structure or void is present between the upper and lower semiconductor packages. The systems and methods described herein also provide more uniform heat spreading across the surface (i.e., in the x-y direction) of the PoP semiconductor package. The systems and methods described herein also advantageously provide a PoP package having an overall lower z-height than overmolded PoP packages.

A package-on-package (PoP) semiconductor package is provided. The PoP semiconductor package may include: a first semiconductor package having an upper surface and a lower surface, wherein at least a portion of the first semiconductor package upper surface includes an exposed die; a second semiconductor package having a top surface and a bottom surface; the second semiconductor package communicably coupled to the first semiconductor package such that a gap forms between the upper surface of the first semiconductor package and the lower surface of the second semiconductor package; and a thermal structure disposed at least partially in the gap, the thermal structure to physically and thermally couple the first semiconductor package to the second semiconductor package; the thermal structure may include: a rigid member having a first surface and a second surface, the second surface opposed across a thickness of the rigid member to the first surface; a first adhesive layer disposed across at least a portion of the first surface of the rigid member; and a second adhesive layer disposed across at least a portion of the second surface of the rigid member.

A package-on-package (PoP) semiconductor package manufacturing method is provided. The method may include: forming a thermal structure by: disposing a first adhesive layer on a first surface of a rigid member; disposing a second adhesive layer on a second surface of the rigid member, the second surface of the rigid member opposed across a thickness of the rigid member from the first surface; physically and thermally coupling an upper surface of a first, exposed die, semiconductor package with a lower surface of a second semiconductor package at least partially encapsulated in a mold compound having a first thermal conductivity by: attaching the first adhesive layer to the lower surface of the second semiconductor package to physically and thermally couple the thermal structure to the second semiconductor package; and attaching the second adhesive layer to the upper surface of the first semiconductor package to physically and thermally couple the thermal structure to the first semiconductor package; where the thermal conductivity of the thermal structure is greater than the first thermal conductivity of the molding compound at least partially encapsulating the second semiconductor package.

A package-on-package (PoP) semiconductor package manufacturing system is provided. The system may include: a thermal structure that includes: means for disposing a first adhesive layer on a first surface of a rigid member; means for disposing a second adhesive layer on a second surface of the rigid member, the second surface of the rigid member opposed across a thickness of the rigid member from the first surface; means for physically and thermally coupling the second adhesive layer to the upper surface of a first semiconductor package; and means for physically and thermally coupling the first adhesive layer to the lower surface of a second semiconductor package, the second semiconductor package at least partially encapsulated in a molding compound; wherein the molding compound at least partially encapsulating the second semiconductor package has a first thermal conductivity; and wherein the thermal conductivity of the thermal structure is greater than the first thermal conductivity of the molding compound at least partially encapsulating the second semiconductor package.

A device that includes a package-on-package (PoP) semiconductor package is provided. The device includes: a first semiconductor package having an upper surface and a lower surface, wherein at least a portion of the first semiconductor package upper surface includes an exposed die; a second semiconductor package having an upper surface and a lower surface; the second semiconductor package communicably coupled to the first semiconductor package such that a gap forms between the upper surface of the first semiconductor package and the lower surface of the second semiconductor package; and a thermal structure disposed at least partially in the gap, the thermal structure to physically and thermally couple the first semiconductor package to the second semiconductor package; the thermal structure including: a rigid member having a first surface and a second surface, the second surface opposed across a thickness of the rigid member to the first surface; a first adhesive layer disposed across at least a portion of the first surface of the rigid member; and a second adhesive layer disposed across at least a portion of the second surface of the rigid member.

As used herein the terms “top,” “bottom,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

As used herein, the term “logically associated” when used in reference to a number of objects, systems, or elements, is intended to convey the existence of a relationship between the objects, systems, or elements such that access to one object, system, or element exposes the remaining objects, systems, or elements having a “logical association” with or to the accessed object, system, or element. An example “logical association” exists between relational databases where access to an element in a first database may provide information and/or data from one or more elements in a number of additional databases, each having an identified relationship to the accessed element. In another example, if “A” is logically associated with “B,” accessing “A” will expose or otherwise draw information and/or data from “B,” and vice-versa.

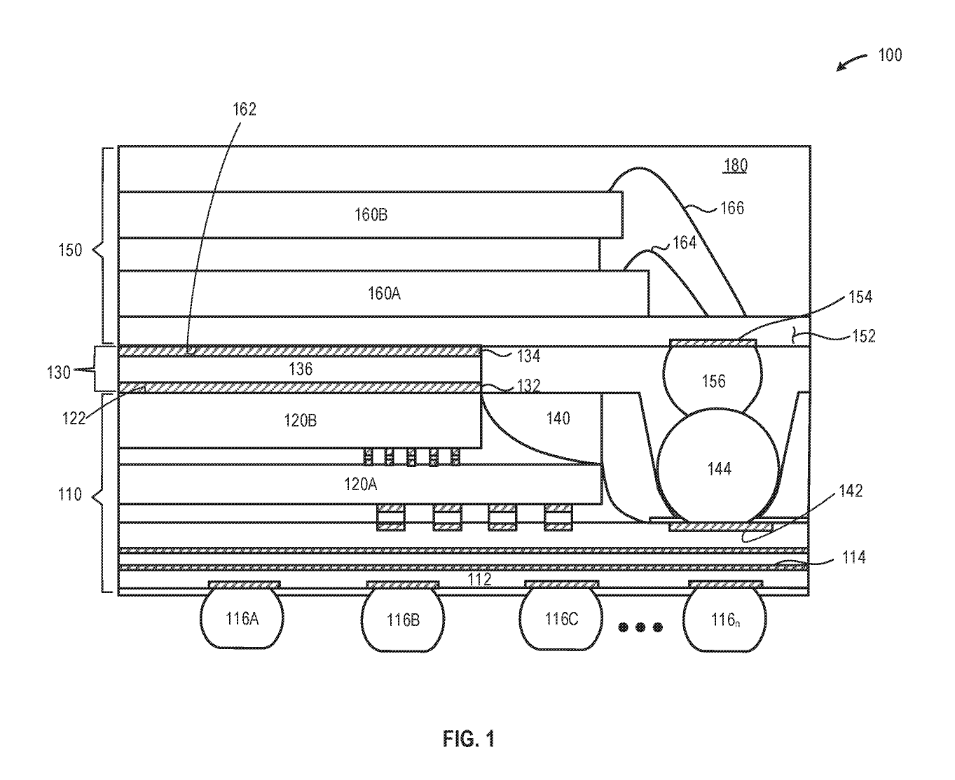

FIG. 1 is a cross-sectional elevation of an illustrative package-on-package (PoP) semiconductor package 100 in which a first semiconductor package 110 and a second semiconductor package 150 are stacked forming a gap between the upper surface 122 of the first semiconductor package 110 and the lower surface 162 of the second semiconductor package 150 and in which a structure 130 that includes a first adhesive layer 132 and a second adhesive layer 134 attached to a rigid substrate 136 thermally conductively couple the first semiconductor package 110 to the second semiconductor package 150, in accordance with at least one embodiment described herein. In embodiments, either or both the first adhesive layer 132 and

the second adhesive layer 134 may include an adhesive film layer in which the adhesive is bonded or otherwise attached to a backing material.

The disclosed PoP semiconductor package 100, including a non-overmolded first semiconductor package 110, beneficially reduces the overall z-height 104 of the PoP package 100, thereby facilitating a thinner electronic device housing. Additionally, the disclosed PoP semiconductor package 100 described herein beneficially reduces the required board mounting area, thereby facilitating an electronic device housing having a smaller footprint than a comparable non-PoP packaged system.

The thermal structure 130 includes a first adhesive layer 132 attached to a first side of a rigid member 136 and a second adhesive layer 134 attached or bonded to a second side or surface of the rigid substrate 136. The thermal structure 130 may have a thermal conductivity greater than the thermal conductivity of the molding compound 180 used to encapsulate the second semiconductor package 150. The thermal structure 130 may have a thermal conductivity of greater than: about 13 W/mK; about 5 W/mk; about 10 W/mK; about 15 W/mK; about 20 W/mK; about 30 W/mK; about 40 W/mK; or about 50 W/mK. In embodiments, the thermal structure 130 may have an overall thickness of less than: about 50 micrometers (μm); about 70 μm; about 90 μm; about 110 μm; or about 130 μm.

In embodiments, either or both the first adhesive layer 132 and/or the second adhesive layer 134 may include a die attachment film (DAF). In some embodiments, the first adhesive layer 132 may include an adhesive material that is evenly distributed across the lower surface of the rigid substrate 136. In some embodiments, the second adhesive layer 134 may include an adhesive material that is evenly distributed across the upper surface of the rigid substrate 136. In such embodiments, the adhesive may be applied to the rigid member 136 using any currently available of future developed adhesive deposition process, including, but not limited to, spinning, spraying, printing, and similar.

In embodiments, the first adhesive layer 132 and/or the second adhesive layer 134 may have a thermal conductivity of greater than: about 3 W/mK; about 5 W/mk; about 10 W/mK; about 15 W/mK; about 20 W/mK; about 30 W/mK; about 40 W/mK; or about 50 W/mK. In embodiments, the first adhesive layer 132 and/or the second adhesive layer 134 may include an organic polymeric film having an adhesive, such as a thermally activated adhesive, disposed on both sides of the film. The first adhesive layer 132 and/or the second adhesive layer 134 may have a film thickness of less than: about 10 micrometers (μm); about 20 μm; about 30 μm; about 40 μm; or about 50 μm. In at least one embodiment, the first adhesive layer 132 may include a die attach film (DAF) having at least one peelable layer and/or at least one peelable backgrind tape layer. In at least one embodiment, the second adhesive layer 134 may include a die attach film (DAF) having at least one peelable layer and/or at least one dicing tape layer.

The first adhesive layer 132 and the second adhesive layer 134 are disposed on opposed sides or surfaces of the rigid member 136. Attaching the adhesive layers to the rigid member 136 eases the handling of the normally flexible adhesive layers. In embodiments, the rigid member 136 may include one or more metals and/or metal alloys, such copper or one or more copper containing alloys. In embodiments, the rigid member 136 may include silicon or one or more silicon containing compounds. In embodiments, the rigid member 136 may include one or more inert materials, such as glass. In embodiments, the rigid member 136 may include one or more materials suitable for thinning using one or more material removal processes such as grinding, chemical-mechanical planarization, and similar. The rigid member 136 may have a thermal conductivity of greater than: about 35 Watts per meter per Kelvin (W/mK); about 50 W/mK; about 75 W/mK; about 100 W/mK; about 125 W/mK; or about 1?50 W/mK. The rigid member 136 may have a final or finished (i.e., after being subjected to one or more material removal processes) thickness of from: about 10 micrometers (μm) to about 90 μm; about 20 μm to about 80 μm; or about 30 μm to about 70 μm.

The first semiconductor package 110 may include a stacked die semiconductor package that includes any number of stacked semiconductor dies 120A-120n (collectively, “semiconductor dies 120”). As depicted in FIG. 1, the first semiconductor package 110 includes a first semiconductor die 120A and a second semiconductor die 120B. In some embodiments, the first semiconductor package 110 may include a stacked die semiconductor package in which the top or uppermost semiconductor die 120n is at least partially exposed, i.e., an exposed die semiconductor package. In some embodiments, the first semiconductor package 110 may be thinned to accommodate the thickness of the thermal structure 130 to minimize the impact on the z-height of the completed PoP semiconductor package 100. In embodiments, the first semiconductor package 110 may be thinned by less than: about 10 micrometers (μm); about 30 μm; about 50 μm; about 70 μm; or about 90 μm to accommodate the disposal of the thermal structure 130 between the first semiconductor package 110 and the second semiconductor package 150. The first semiconductor package 110 includes a substrate 112 having any number of layers that include one or more conductive traces 114 on which the semiconductor dies 120 are physically mounted and to which at least some of the semiconductor dies 120 are communicably and conductively coupled.

The second semiconductor package 150 may also include a stacked die semiconductor package that includes any number of stacked semiconductor dies 160A-160n (collectively, “semiconductor dies 160”). As depicted in FIG. 1, the second semiconductor package 150 includes a first semiconductor die 160A stacked with a second semiconductor die 160B. A plurality of conductors 164 (wire bonds, solder bumps, etc.) connect the first semiconductor die 160A to conductive pads 154 disposed on the substrate 152 of the second semiconductor package 150. Similarly, a plurality of conductors 166 (wire bonds, solder bumps, etc.) communicably couple the second semiconductor die 160B to conductive pads 154 disposed on the substrate 152 of the second semiconductor package 150. In embodiments, the second semiconductor package 150 may be partially or completely encapsulated in molding compound 180. Although depicted as an overmolded semiconductor package in FIG. 1, in embodiments, the second semiconductor package 150 may also include an exposed die semiconductor package in which the second semiconductor die 160B forms at least a portion of the upper surface of the second semiconductor package 150.

The first semiconductor package 110 and the second semiconductor package 150 are conductively and communicably coupled using a plurality of conductive structures. As depicted in FIG. 1, a plurality of solder balls 144 may be disposed on a respective plurality of pads 142 disposed in, on, or about the first semiconductor package substrate 112 and a plurality of solder balls 156 may be disposed on a respective plurality of conductive pads 154 disposed in, on, or about the second semiconductor package substrate 152. In embodiments, the first semiconductor package 110 and the second semiconductor package 150 may be communicably coupled using the solder balls 144 and 156. For example, the first semiconductor package 110 and the second semiconductor package 150 may be communicably coupled by melting the solder balls 144 and 156 using a reflow process. After coupling the first semiconductor package 110 to the second semiconductor package 150, a gap exists between the upper surface 122 of the first semiconductor package 110 and the lower surface 162 of the second semiconductor package 150.

Left unfilled, the air-filled space or gap between the first semiconductor package 110 and the second semiconductor package 150 adversely impacts the flow of heat (i.e., the heat transfer) from the first semiconductor package 110 to the second semiconductor package 150. Disposing the thermal structure 130 in the gap between the first semiconductor package 110 and the second semiconductor package 150 thermally conductively couples the first semiconductor package 110 to the second semiconductor package 150, improving heat flow from the first semiconductor package 110 to the second semiconductor package 150. In addition, the thermal structure 130 beneficially improves heat distribution across the upper surface 122 of the first semiconductor package 110 reducing the temperature of any hot spots on the supper surface of the first semiconductor package 110. In embodiments, the thermal structure 130 may have a higher thermal conductivity than the molding compound 180 used to encapsulate the second semiconductor package 150 to further enhance the heat transfer from the first semiconductor package 110 and the heat distribution across the upper surface 122 of the first semiconductor package 110.

The first semiconductor package 110 may include any number and/or combination of semiconductor dies 120A-120n. In embodiments, the semiconductor dies 120 forming the first semiconductor package 110 may include: a system-in-a-package (SiP); a system-on-a-chip (SoC); an application specific integrated circuit (ASIC); a reduced instruction set computer (RISC); a digital signal processor (DSP); a programmable gate array (PGA); or any other device, collection of devices and/or system capable of executing machine readable instructions and accessing one or more storage devices. The first semiconductor package 110 may have any physical size, shape or configuration.

As depicted in FIG. 1, in embodiments, the first semiconductor package 110 may be fabricated using an exposed die molding process in which the semiconductor dies 120 are surrounded by a molding compound 140. In such an embodiment, the uppermost semiconductor die 120n remains at least partially exposed after curing the molding compound 140. In such embodiments, the thereby forming a portion of the upper surface 122 of the first semiconductor package 110.

The second semiconductor package 150 may include any number and/or combination of semiconductor dies 160A-160n. In embodiments, the semiconductor dies 160 forming the second semiconductor package 150 may include, but is not limited to: a low power double data rate (LPDDR1, LPDDR2, LPDDR3, LPDDR4) random access memory; a low power standard data rate (LPSDR) random access memory; a 3D NAND; a universal flash storage (UFS) memory; an embedded multi-media controller (e.MMC); or combinations thereof. The second semiconductor package 150 may have any physical size, shape, or configuration. In some embodiments, the second semiconductor package 150 may occupy a physically smaller area than the first semiconductor package 110. For example, the surface area of the lower surface 162 of the second semiconductor package 150 may be less than the surface area of the upper surface 122 of the first semiconductor package 110. The first semiconductor package 110 and the second semiconductor package 150 may be physically, communicably, and/or conductively coupled using mass reflow or thermal compression bonding. Example mass reflow techniques include, but are not limited to: forced convection; infrared radiation; vapor phase; laser; hot bar; or any combination thereof.

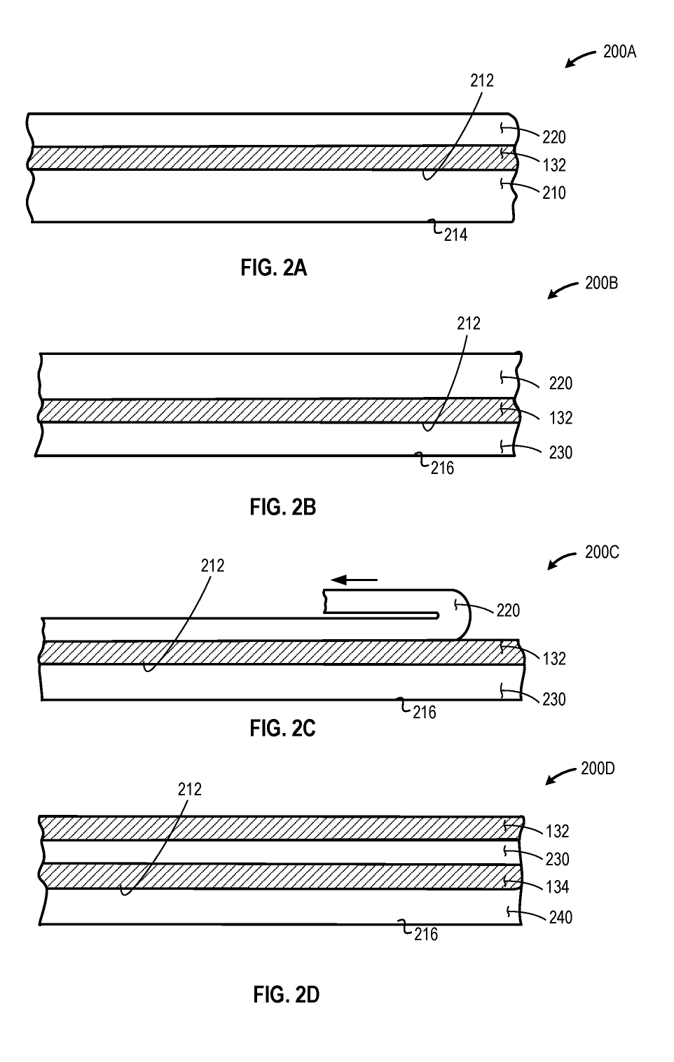

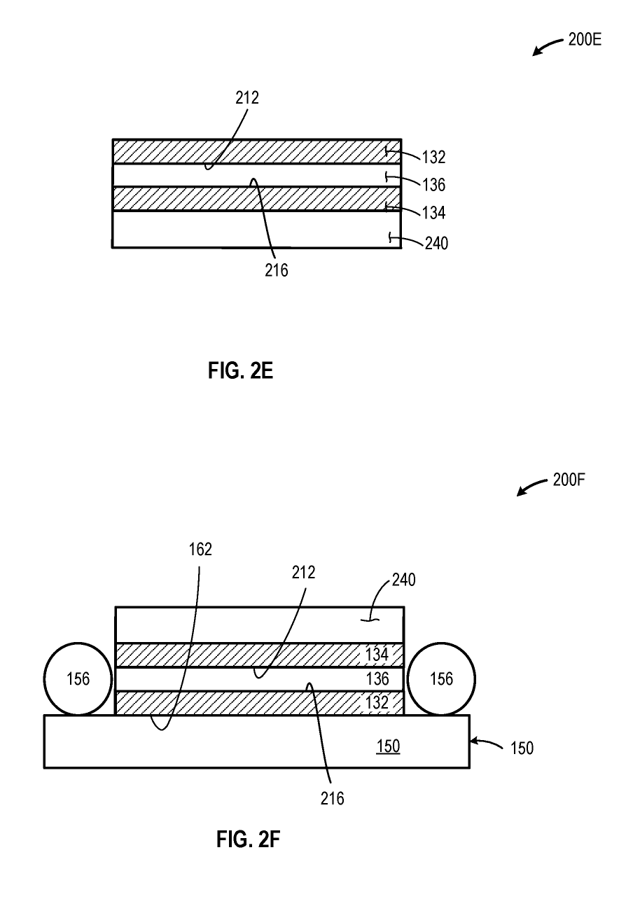

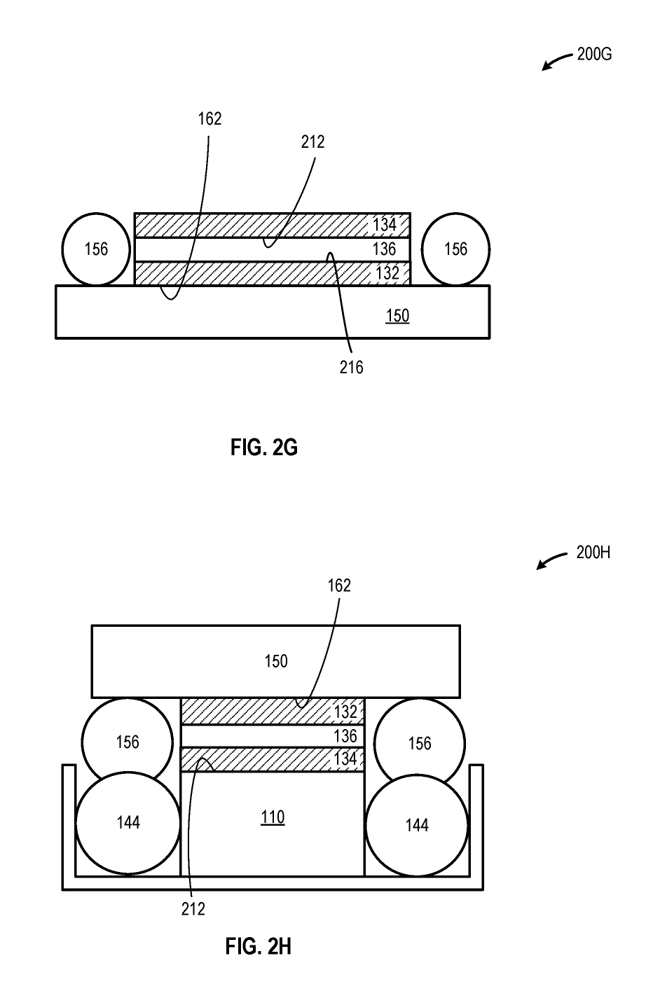

FIGS. 2A through 2H are cross-sectional elevations that depict a non-exclusive, illustrative, fabrication method of an example PoP semiconductor package 100 that includes a thermal structure 130 disposed between the first semiconductor package 110 and the second semiconductor package 150, in accordance with at least one embodiment described herein.

FIG. 2A is a cross-sectional elevation that depicts a non-exclusive, illustrative, fabrication method of a thermal structure 130, in accordance with at least one embodiment described herein. As depicted in FIG. 2A, a first adhesive layer 132 and a peelable backgrind tape 220 is disposed across all or a portion of a first surface 212 of a substrate 210. In embodiments, the substrate 210 may include a silicon wafer having a thickness of from about 150 micrometers (μm) to about 750 μm and a diameter of from about 100 millimeters (mm) to about 600 mm. The first adhesive layer 132 may cover all or a portion of the substrate 210.

In embodiments, the substrate 210 may include one or more metals and/or metal alloys, such copper or one or more copper containing alloys. In embodiments, the substrate 210 may include one or more inert materials, such as glass. In embodiments, the substrate 210 may include one or more materials suitable for thinning using one or more material removal processes such as grinding, chemical-mechanical planarization, and similar. The substrate 210 may have a thermal conductivity of greater than: about 35 Watts per meter per Kelvin (W/mK); about 50 W/mK; about 75 W/mK; about 100 W/mK; about 125 W/mK; or about 50 W/mK.

The first adhesive layer 132 may include any number and/or combination of currently available or future developed adhesive films suitable for use in physically coupling semiconductor dies and/or semiconductor packages. In embodiments, the first adhesive layer 132 may include one or more electrically non-conductive or insulative materials having an electrical resistance in excess of: about 250K Ohms per square centimeter (Ω-cm); about 500 K Ω-cm; about 1 MΩ-cm; about 2 MΩ-cm; about 5 MΩ-cm; about 10MΩ-cm; or about 100MΩ-cm. In embodiments, the first adhesive layer 132 may include an electrically conductive material having an electrical resistance of less than: about 1 Ohm per square centimeter (Ω-cm); about 0.1 Ω-cm; about 0.01 Ω-cm; about 0.001 Ω-cm; or less than about 0.0001 Ω-cm. In embodiments, the first adhesive layer 132 may include a die attach film (DAF).

In some implementations, the first adhesive layer 132 may be detachably attached to a peelable back grinding tape 220. The back grinding tape 220 may include any currently available or future developed back grind tape suitable for protecting the rigid substrate material 136 against surface damage during back grinding. The back grinding tape 220 may prevent surface contamination of the rigid member 136 caused by infiltration of grinding fluid and/or debris generated during the back grinding process. In embodiments, the back grinding tape 220 may include an ultraviolet (UV) light curable back grinding tape.

FIG. 2B is a cross-sectional elevation that depicts a non-exclusive, illustrative, fabrication method of a thermal structure 130 after back grinding the substrate 210, in accordance with at least one embodiment described herein. The substrate 210 may be unacceptably thick which, if left untouched, would adversely impact the z-dimension of the finished PoP semiconductor package 100. In embodiments, the substrate 210 may be thinned using any currently available or future developed material removal process. Such material removal processes may include, but are not limited to, a chemical material removal process, a mechanical material removal process, or an electrolytic material removal process. Example processes include, but are not limited to: mechanical grinding of the substrate 210 and chemical/mechanical planarization of the substrate 210. After thinning, the residual substrate 210 attached to the first adhesive layer 132 forms a thinned substrate 230.

For example, using a silicon wafer as a substrate 220, the wafer may have an initial thickness of from about 600 micrometers (μm) to about 750 μm. Using a mechanical grinding process, the silicon wafer forming the substrate 210 may be thinned to provide a thinned substrate 230 having a final thickness of from about 10 micrometers (μm) to about 90 μm. For example, in at least one embodiment, a silicon wafer providing the substrate 210 may be thinned from 750 μm starting thickness to 50 μm final thickness.

FIG. 2C is a cross-sectional elevation that depicts a non-exclusive, illustrative, fabrication method of a thermal structure 130 that includes the removal (i.e., peeling) of the back grinding tape 220 from the first adhesive layer 132, in accordance with at least one embodiment described herein. After back grinding is complete and the substrate 210 is thinned to provide the thinned substrate 230, the back grinding tape 220 may be removed from the first adhesive layer 132.

FIG. 2D is a cross-sectional elevation that depicts a non-exclusive, illustrative, fabrication method of a thermal structure 130 that includes the deposition of the second adhesive layer 134 on the second surface 216 of the thinned substrate 230, in accordance with at least one embodiment described herein. In embodiments, the second adhesive layer 134 may include dicing tape 240 on the surface of the second adhesive film 134 opposite the thinned substrate 230. The second adhesive layer 134 and the dicing tape 240 may be disposed across all or a portion of the second surface 216 of the thinned substrate 230.

The second adhesive layer 134 may include any number and/or combination of currently available or future developed adhesive films suitable for use in physically coupling semiconductor dies and/or semiconductor packages. In embodiments, the second adhesive layer 134 may have the same composition as the first adhesive layer 132. In embodiments, the second adhesive layer 134 may include one or more electrically non-conductive or insulative materials having an electrical resistance in excess of: about 250K Ohms per square centimeter (Ω-cm); about 500 K Ω-cm; about 1 MΩ-cm; about 2 MΩ-cm; about 5 MΩ-cm; about 10MΩ-cm; or about 100MΩ-cm. In embodiments, the second adhesive layer 134 may include an electrically conductive material having an electrical resistance of less than: about 1 Ohm per square centimeter (Ω-cm); about 0.1 Ω-cm; about 0.01 Ω-cm; about 0.001 Ω-cm; or less than about 0.0001 Ω-cm. In embodiments, the second adhesive layer 134 may include a semiconductor die attach film (DAF).

The second adhesive layer 134 may be detachably attached to a peelable dicing tape 240. The dicing tape 240 may include any currently available or future developed dicing tape suitable holding the pieces of the thermal member 130 together during the singulation or separation process. The dicing tape 240 may include a PVC, polyolefin, or polyethylene backing material with an adhesive to hold the singulated thermal members 130 in place. The dicing tape 240 may have any thickness. For example, the dicing tape 240 may have a thickness of from about 75 micrometers (μm) to about 150 μm. In embodiments, the dicing tape 240 may include an ultraviolet (UV) dicing tape in which the adhesive bond between the dicing tape 240 and the second adhesive layer 134 may be weakened or broken through exposure to UV light after dicing.

FIG. 2E is a cross-sectional elevation that depicts a non-exclusive, illustrative, fabrication method of a thermal structure 130 after the thermal structure 130 has been singulated in preparation for deposition or placement between the first semiconductor package 110 and the second semiconductor package 150, in accordance with at least one embodiment described herein. After disposing the second adhesive layer 134 and the dicing tape 230 on the second surface 216 of the thinned substrate 230, the thinned substrate 230 may be singulated to provide a plurality of thermal members 130. As depicted in FIG. 2E, each of the thermal members 130 includes a rigid substrate 136 having a first adhesive layer 132 disposed across a first surface 212 and a second adhesive layer 134 disposed across a second surface 216 that opposes the first surface 212 across the thickness of the rigid member 136. The dicing tape remains disposed on the second adhesive layer 134 opposite the rigid member 136.

FIG. 2F is a cross-sectional elevation that depicts a non-exclusive, illustrative, fabrication method of a thermal structure 130 coupled, by the first adhesive layer 132, to a lower surface 162 of a second semiconductor package 150, in accordance with at least one embodiment described herein. In embodiments, the thermal structure 130 may be coupled to the lower surface 162 of the second semiconductor package 150 using the first adhesive layer 132. In some implementations, the first adhesive layer 132 may include one or more ultraviolet (UV) curable adhesives and the thermal structure 130 may be physically and thermally coupled to the second semiconductor package 150 via exposure to UV light for a defined duration. In some implementations, the first adhesive layer 132 may include one or more thermally curable adhesives and the thermal structure 130 may be physically and thermally coupled to the second semiconductor package 150 via exposure to an elevated temperature for a defined duration.

Although the dicing tape 240 is depicted in FIG. 2F as attached to the singulated thermal structure 130, in some implementations the dicing tape 240 may be removed during the singulated thermal structure pick operation. In such implementations, the dicing tape 240 would not be present in FIGS. 2F through 2H.

FIG. 2G is a cross-sectional elevation that depicts a non-exclusive, illustrative, fabrication method of a thermal structure 130 that includes the removal (i.e., peeling) of the dicing tape 240 from the second adhesive layer 134, in accordance with at least one embodiment described herein. After physically and thermally coupling the thermal member 130 to the lower surface 162 of the second semiconductor package 150, the dicing tape 240 may be removed from the second adhesive layer 134, exposing all or a portion of the second film layer 134.

FIG. 2H is a cross-sectional elevation that depicts a non-exclusive, illustrative, fabrication method of a PoP semiconductor package 100 that includes a thermal structure 130 physically and thermally coupling the upper surface 122 of the first semiconductor package 110 with the lower surface 162 of the second semiconductor package 150, in accordance with at least one embodiment described herein. As depicted in FIG. 2H, the second adhesive layer 134 may physically and thermally couple the thermal member 130 to the upper surface 122 of the first semiconductor package 110. A plurality of conductive members 144 (e.g., solder balls 144) coupled to the first semiconductor package 110 and a plurality of conductive members 156 (e.g., solder balls 156) communicably couple the first semiconductor package 110 with the second semiconductor package 150.

In some implementations, the second adhesive layer 134 may include one or more ultraviolet (UV) curable adhesives and the thermal structure 130 may be physically and thermally coupled to the first semiconductor package 110 via exposure to UV light for a defined duration. In some implementations, the second adhesive layer 134 may include one or more thermally curable adhesives and the thermal structure 130 may be physically and thermally coupled to the first semiconductor package 110 via exposure to an elevated temperature for a defined duration, for example during a reflow process to conductively couple the first semiconductor package 110 to the second semiconductor package 150.

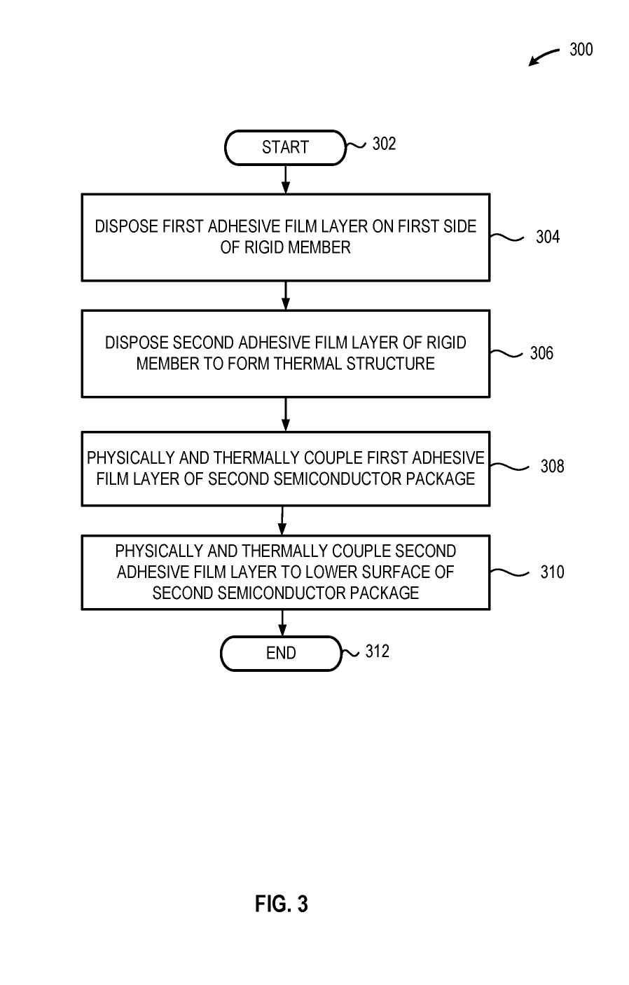

FIG. 3 is a high-level flow diagram of an illustrative method 300 of fabricating a PoP semiconductor package 100 that includes a thermal structure 130 to physically and thermally couple a first semiconductor package 110 to a second semiconductor package 150, in accordance with at least one embodiment described herein. The thermal structure 130 includes a first adhesive layer 132 and a second adhesive layer 134 disposed on opposing sides of a rigid member 136. The presence of the rigid member 136 beneficially provides a degree of rigidity to the normally flimsy adhesive layers thereby permitting the handling and positioning of the thermal structure 130 between the first semiconductor package 132 and the second semiconductor package 134 during the PoP assembly process. The method 300 commences at 302.

At 304, the first adhesive layer 132 is disposed on a first surface 212 of a rigid substrate 230. In embodiments, the first adhesive layer 132 may include a die attach film. In embodiments, the first adhesive layer 132 may be disposed on, across, or about a first surface 212 of a rigid silicon wafer substrate 230.

In embodiments, the first adhesive layer 132 may include a back grinding tape 220. In such embodiments, the back grinding tape 220 may remain affixed to the first adhesive layer 132 until after the rigid substrate 230 is thinned.

At 306, the second adhesive layer 134 is disposed on a second surface 216 of a rigid substrate 230. In embodiments, the second adhesive layer 134 may include a die attach film. In embodiments, the second adhesive layer 134 may be disposed on, across, or about a second surface 216 of the rigid silicon wafer substrate 230. In embodiments, the second adhesive layer 134 may be applied to the second surface 216 of the thinned rigid silicon wafer substrate.

In embodiments, the second adhesive layer 134 may include a dicing tape 240. In such embodiments, the dicing tape 240 may remain affixed to the second adhesive layer 134 until after the thinned rigid substrate 230 is singulated to provide a plurality of thermal structures 130. In embodiments, the dicing tape 240 may remain affixed to the second adhesive layer 134 until after the first adhesive layer 132 included in the thermal structure 130 is physically and thermally coupled to the lower surface 162 of a second semiconductor package 150.

At 308, using the exposed first adhesive layer 132, the thermal structure 130 is attached to a lower surface 162 of the second semiconductor package 150. Attaching the thermal structure 130 to the lower surface 162 of the second semiconductor package 150 physically and thermally couples the thermal structure 130 to the second semiconductor package 150.

In embodiments, after attaching the thermal structure 130 to the lower surface 162 of the second semiconductor package 150, the dicing tape 240 may be removed from the second adhesive layer 134, exposing the second adhesive layer 134.

At 310, using the exposed second adhesive layer 134, the thermal structure 130 is attached to an upper surface 122 of the first semiconductor package 110. Attaching the thermal structure 130 to the upper surface 122 of the first semiconductor package 150 physically and thermally couples the thermal structure 130 to the first semiconductor package 110. Thermally coupling the thermal structure 130 to the upper surface of the first semiconductor package 110 permits a more even heat distribution across the upper surface 122 of the first semiconductor package 110, reducing the temperature of hotspots on the upper surface 122 of the first semiconductor package 110. Additionally, attaching the thermal structure 130 to the first semiconductor package 110 and the second semiconductor package 150 physically and thermally couples the first semiconductor package 110 to the second semiconductor package 150. The method 300 concludes at 312.

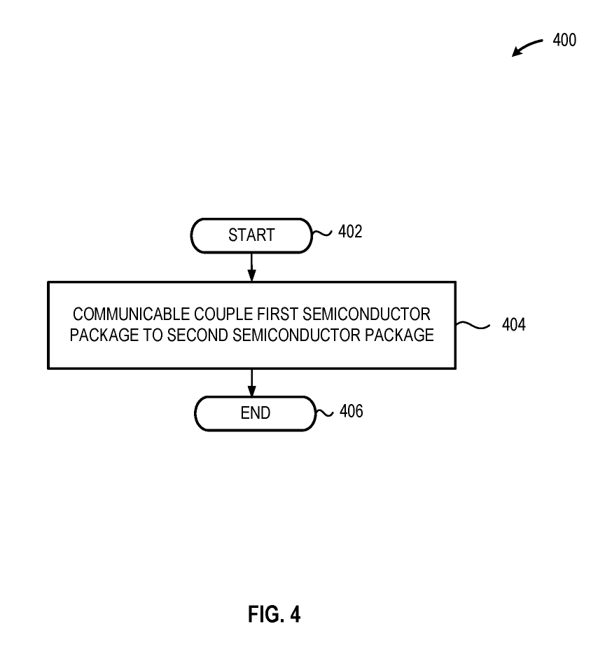

FIG. 4 is a high-level flow diagram of an illustrative method 400 of fabricating a PoP semiconductor package 100 that includes a thermal structure 130 to physically and thermally couple a first semiconductor package 110 to a second semiconductor package 150, in accordance with at least one embodiment described herein. The method 400 may be used in conjunction with the method 300 described in detail in FIG. 3. In embodiments, the first semiconductor package 110 and the second semiconductor package 150 in the PoP semiconductor package 100 may be communicably coupled using one or more conductive structures. The method 400 commences at 402.

At 404, the first semiconductor package 110 is communicably coupled to the second semiconductor package 150 using one or more conductive structures. In embodiments, one or more conductive structures, such as one or more solder balls 144, conductively coupled to the first semiconductor package 110 may be communicably coupled to one or more conductive structures, such as one or more solder balls 156, conductively coupled to the second semiconductor package 150. The method 400 concludes at 406.

While FIGS. 3 and 4 illustrate various operations according to one or more embodiments, it is to be understood that not all of the operations depicted in FIGS. 3 and 4 are necessary for other embodiments. Indeed, it is fully contemplated herein that in other embodiments of the present disclosure, the operations depicted in FIGS. 3 and 4, and/or other operations described herein, may be combined in a manner not specifically shown in any of the drawings, but still fully consistent with the present disclosure. Thus, claims directed to features and/or operations that are not exactly shown in one drawing are deemed within the scope and content of the present disclosure.

As used in this application and in the claims, a list of items joined by the term “and/or” can mean any combination of the listed items. For example, the phrase “A, B and/or C” can mean A; B; C; A and B; A and C; B and C; or A, B and C. As used in this application and in the claims, a list of items joined by the term “at least one of” can mean any combination of the listed terms. For example, the phrases “at least one of A, B or C” can mean A; B; C; A and B; A and C; B and C; or A, B and C.

As used in any embodiment herein, the terms “system” or “module” may refer to, for example, software, firmware and/or circuitry configured to perform any of the aforementioned operations. Software may be embodied as a software package, code, instructions, instruction sets and/or data recorded on non-transitory computer readable storage mediums. Firmware may be embodied as code, instructions or instruction sets and/or data that are hard-coded (e.g., nonvolatile) in memory devices. “Circuitry”, as used in any embodiment herein, may comprise, for example, singly or in any combination, hardwired circuitry, programmable circuitry such as computer processors comprising one or more individual instruction processing cores, state machine circuitry, and/or firmware that stores instructions executed by programmable circuitry or future computing paradigms including, for example, massive parallelism, analog or quantum computing, hardware embodiments of accelerators such as neural net processors and non-silicon implementations of the above. The circuitry may, collectively or individually, be embodied as circuitry that forms part of a larger system, for example, an integrated circuit (IC), system on-chip (SoC), desktop computers, laptop computers, tablet computers, servers, smartphones, etc.

Any of the operations described herein may be implemented in a system that includes one or more mediums (e.g., non-transitory storage mediums) having stored therein, individually or in combination, instructions that when executed by one or more processors perform the methods. Here, the processor may include, for example, a server CPU, a mobile device CPU, and/or other programmable circuitry. Also, it is intended that operations described herein may be distributed across a plurality of physical devices, such as processing structures at more than one different physical location. The storage medium may include any type of tangible medium, for example, any type of disk including hard disks, floppy disks, optical disks, compact disk read-only memories (CD-ROMs), rewritable compact disks (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, Solid State Disks (SSDs), embedded multimedia cards (eMMCs), secure digital input/output (SDIO) cards, magnetic or optical cards, or any type of media suitable for storing electronic instructions. Other embodiments may be implemented as software executed by a programmable control device.

Thus, the present disclosure is directed to systems and methods for improving heat distribution and heat removal efficiency in PoP semiconductor packages. A PoP semiconductor package includes a first semiconductor package that is physically, communicably, and conductively coupled to a stacked second semiconductor package. The first semiconductor package may include a die stack in which the uppermost die remains exposed (i.e., the first semiconductor package may be an exposed die package). The second semiconductor package may include a die stack in which all dies are encapsulated in molding compound. A gap forms between the upper surface of the first semiconductor package and the lower surface of the second semiconductor package. A thermal structure is physically and thermally coupled to the upper surface of the first semiconductor package and to the lower surface of the second semiconductor package. The thermal structure has opposed first and second surfaces and includes a first adhesive layer disposed across the first surface and a second adhesive layer disposed across the second surface. The thermal conductivity of the thermal structure is greater than the thermal conductivity of the molding compound at least partially encapsulating the second semiconductor package. The first adhesive layer physically and thermally couples the thermal structure to the lower surface of the second semiconductor package. The second adhesive layer physically and thermally couples the thermal structure to the upper surface of the first semiconductor package. The presence of the thermal structure in the gap between the first semiconductor package and the second semiconductor package beneficially and advantageously distributes heat across the upper surface of the first semiconductor package and enhances thermal flow from the first semiconductor package to the second semiconductor package.

The following examples pertain to further embodiments. The following examples of the present disclosure may comprise subject material such as at least one device, a method, at least one machine-readable medium for storing instructions that when executed cause a machine to perform acts based on the method, means for performing acts based on the method and/or a system for improving and enhancing lateral heat distribution across the upper surface of a first semiconductor package in a PoP semiconductor package and improving and enhancing the flow of heat from a first semiconductor package to a second semiconductor package within a PoP semiconductor package.

According to example 1, there is provided a package-on-package (PoP) semiconductor package. The PoP semiconductor package may include: a first semiconductor package having an upper surface and a lower surface, wherein at least a portion of the first semiconductor package upper surface includes an exposed die; a second semiconductor package having a top surface and a bottom surface; the second semiconductor package communicably coupled to the first semiconductor package such that a gap forms between the upper surface of the first semiconductor package and the lower surface of the second semiconductor package; and a thermal structure disposed at least partially in the gap, the thermal structure to physically and thermally couple the first semiconductor package to the second semiconductor package; the thermal structure may include: a rigid member having a first surface and a second surface, the second surface opposed across a thickness of the rigid member to the first surface; a first adhesive layer disposed across at least a portion of the first surface of the rigid member; and a second adhesive layer disposed across at least a portion of the second surface of the rigid member.

Example 2 may include elements of example 1 where the first adhesive layer may include a first die attachment film layer.

Example 3 may include elements of example 2 where the second adhesive layer may include a second die attachment film layer.

Example 4 may include elements of example 3 where the thermal structure may include at least one of: a silicon substrate, a glass substrate, or a copper substrate on which the first adhesive layer and the second adhesive layer are disposed.

Example 5 may include elements of example 1 where the second semiconductor package may include a die stack encapsulated in a molding compound having a first thermal conductivity; wherein the thermal structure has a second thermal conductivity; where the second thermal conductivity is greater than the first thermal conductivity.

Example 6 may include elements of example 1 where the first semiconductor package may include a system-on-a-chip (SoC).

Example 7 may include elements of example 1 where the second semiconductor package may include a stacked memory die encapsulated in a molding compound.

Example 8 may include elements of example 1 where, in operation, a thermal output of the first semiconductor package exceeds a thermal output of the second semiconductor package.

Example 9 may include elements of example 1 where the upper surface of the first semiconductor package comprises a surface having a first area and the lower surface of the second semiconductor package comprises a surface having a second area, the second area less than the first area.

Example 10 may include elements of any of examples 1 through 9, and the PoP semiconductor package may additionally include a plurality of conductive structures to communicably couple the first semiconductor package to the second semiconductor package.

According to example 11, there is provided a package-on-package (PoP) semiconductor package manufacturing method. The method may include: forming a thermal structure by: disposing a first adhesive layer on a first surface of a rigid member; disposing a second adhesive layer on a second surface of the rigid member, the second surface of the rigid member opposed across a thickness of the rigid member from the first surface; physically and thermally coupling an upper surface of a first, exposed die, semiconductor package with a lower surface of a second semiconductor package at least partially encapsulated in a mold compound having a first thermal conductivity by: attaching the first adhesive layer to the lower surface of the second semiconductor package to physically and thermally couple the thermal structure to the second semiconductor package; and attaching the second adhesive layer to the upper surface of the first semiconductor package to physically and thermally couple the thermal structure to the first semiconductor package; where the thermal conductivity of the thermal structure is greater than the first thermal conductivity of the molding compound at least partially encapsulating the second semiconductor package.

Example 12 may include elements of example 11 where disposing a first adhesive layer on a first surface of a rigid member may include: disposing the first adhesive layer on a first surface of a rigid silicon wafer substrate.

Example 13 may include elements of example 12 where disposing the first adhesive layer on a first surface of a rigid silicon wafer substrate may further include: disposing a first adhesive layer that includes a back grinding tape on the first surface of the rigid silicon wafer substrate; reducing the thickness of the rigid silicon wafer substrate to a thickness of from about 10 micrometers (μm) to about 40 μm; and removing the back grinding tape.

Example 14 may include elements of example 13 where removing the backgrind tape may include: separating the back grinding tape from the first adhesive layer to expose at least a portion of the first adhesive layer.

Example 15 may include elements of example 14 where disposing a second adhesive layer on a second surface of the rigid member may include: disposing a second adhesive layer that includes a dicing tape on the second surface of the rigid member; singulating the rigid silicon wafer substrate; and removing the dicing tape from the singulated rigid silicon wafer substrate after attaching the first adhesive layer to the lower surface of the second semiconductor package and prior to attaching the second adhesive layer to the upper surface of the first semiconductor package.

Example 16 may include elements of example 11 where disposing a first adhesive layer on a first surface of a rigid member may further include: disposing the first adhesive layer on the first surface of a rigid member, the rigid member comprising at least one of: a rigid silicon wafer substrate; a rigid metal substrate; or a rigid glass substrate.

Example 17 may include elements of any of examples 11 through 16 where physically and thermally coupling an upper surface of a first, exposed die, semiconductor package with a lower surface of a second semiconductor package may include: physically and thermally coupling an upper surface of a stacked die system-on-a-chip (SoC) first semiconductor package to a lower surface of a memory semiconductor package.

Example 18 may include elements of example 17, and the method may additionally include: communicably coupling the first semiconductor package with the second semiconductor package.

According to example 19, there is provided a package-on-package (PoP) semiconductor package manufacturing system. The system may include: a thermal structure that includes: means for disposing a first adhesive layer on a first surface of a rigid member; means for disposing a second adhesive layer on a second surface of the rigid member, the second surface of the rigid member opposed across a thickness of the rigid member from the first surface; means for physically and thermally coupling the second adhesive layer to the upper surface of a first semiconductor package; and means for physically and thermally coupling the first adhesive layer to the lower surface of a second semiconductor package, the second semiconductor package at least partially encapsulated in a molding compound; wherein the molding compound at least partially encapsulating the second semiconductor package has a first thermal conductivity; and wherein the thermal conductivity of the thermal structure is greater than the first thermal conductivity of the molding compound at least partially encapsulating the second semiconductor package.

Example 20 may include elements of example 19 where the means for disposing a first adhesive layer on a first surface of a rigid member may include: means for disposing the first adhesive layer on a first surface of a rigid silicon wafer substrate.

Example 21 may include elements of example 20 where the means for disposing the first adhesive layer on a first surface of a rigid silicon wafer substrate may further include: means for disposing a first adhesive layer that includes a back grinding tape across the first surface of the rigid silicon wafer substrate; means for reducing the thickness of the rigid silicon wafer substrate to a thickness of from about 10 micrometers (μm) to about 40 μm; and means for removing the back grinding tape.

Example 22 may include elements of example 21 where the means for removing the back grinding tape may include: means for separating the back grinding tape from a surface of the first adhesive layer to expose at least a portion of the first adhesive layer.

Example 23 may include elements of example 22 where the means for disposing a second adhesive layer on a second surface of the rigid member may further include: means for disposing a second adhesive layer that includes a dicing tape across at least a portion of the second surface of the rigid silicon wafer substrate; means for singulating the rigid silicon wafer substrate; and means for separating the dicing tape from the singulated rigid silicon wafer substrate after attaching the first adhesive layer to the lower surface of the second semiconductor package and prior to attaching the second adhesive layer to the upper surface of the first semiconductor package.

Example 24 may include elements of example 19 where the means for disposing a first adhesive layer on a first surface of a rigid member may further include: means for disposing the first adhesive layer on the first surface of a rigid member comprising at least one of: a rigid silicon wafer substrate; a rigid metal member substrate; or a rigid dielectric substrate.

Example 25 may include elements of any of examples 19 through 24 where the means for means for physically and thermally coupling the second adhesive layer to the upper surface of a first semiconductor package may include: a means for physically and thermally coupling of the second adhesive layer to a stacked die system-on-a-chip (SoC) first semiconductor package; and where the means for physically and thermally coupling the first adhesive layer to the lower surface of a second semiconductor package may include: a means for physically and thermally coupling the first adhesive layer to a lower surface of a memory semiconductor package.

Example 26 may include elements of example 25, and the system may additionally include: means for communicably coupling the first semiconductor package to the second semiconductor package.

According to example 27, there is provided a device that includes: a package-on-package (PoP) semiconductor package that includes: a first semiconductor package having an upper surface and a lower surface, wherein at least a portion of the first semiconductor package upper surface includes an exposed die; a second semiconductor package having an upper surface and a lower surface; the second semiconductor package communicably coupled to the first semiconductor package such that a gap forms between the upper surface of the first semiconductor package and the lower surface of the second semiconductor package; and a thermal structure disposed at least partially in the gap, the thermal structure to physically and thermally couple the first semiconductor package to the second semiconductor package; the thermal structure including: a rigid member having a first surface and a second surface, the second surface opposed across a thickness of the rigid member to the first surface; a first adhesive layer disposed across at least a portion of the first surface of the rigid member; and a second adhesive layer disposed across at least a portion of the second surface of the rigid member.

Example 28 may include elements of example 27 where the first adhesive layer may include a first die attachment film layer.

Example 29 may include elements of example 28 where the second adhesive layer comprises a second die attachment film layer.

Example 30 may include elements of example 29 where the thermal structure may include at least one of: a silicon substrate, a dielectric substrate, or a metal substrate to receive the first adhesive layer and the second adhesive layer.

Example 31 may include elements of example 27 where the second semiconductor package comprises a die stack encapsulated in a molding compound having a first thermal conductivity; where the thermal structure has a second thermal conductivity; and where the second thermal conductivity is greater than the first thermal conductivity.

Example 32 may include elements of example 27 where the first semiconductor package may include a system-on-a-chip (SoC).

Example 33 may include elements of example 27 where the second semiconductor package may include a stacked memory die encapsulated in a molding compound.

Example 34 may include elements of example 27 where, in operation, a thermal output of the first semiconductor package exceeds a thermal output of the second semiconductor package.

Example 35 may include elements of example 27 where the upper surface of the first semiconductor package may include a surface having a first area and the lower surface of the second semiconductor package may include a surface having a second area, the second area less than the first area.

Example 36 may include elements of any of examples 27 through 35, and the device may additionally include: a plurality of conductive structures to communicably couple the first semiconductor package to the second semiconductor package.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents.

1. A package-on-package (PoP) semiconductor package, comprising:
a first semiconductor package having an upper surface and a lower surface;
a second semiconductor package having a top surface and a bottom surface; the second semiconductor package communicably coupled to the first semiconductor package such that a gap forms between the upper surface of the first semiconductor package and the lower surface of the second semiconductor package; and
a thermal structure disposed at least partially in the gap, the thermal structure to physically and thermally couple the first semiconductor package to the second semiconductor package;
the thermal structure including:
a rigid member having a first surface and a second surface, the second surface opposed across a thickness of the rigid member to the first surface;
a first adhesive layer comprising one or more materials and disposed across at least a portion of the first surface of the rigid member; and
a second adhesive layer comprising the same one or more materials and disposed across at least a portion of the second surface of the rigid member.

2. The PoP semiconductor package of claim 1 wherein at least a portion of the first semiconductor package upper surface includes an exposed die.

3. The PoP semiconductor package of claim 1 wherein the first adhesive layer comprises a first die attachment film layer.

4. The PoP semiconductor package of claim 3 wherein the second adhesive layer comprises a second die attachment film layer.

5. The PoP semiconductor package of claim 4 wherein the rigid member comprises at least one of: a silicon substrate, a glass substrate, or a copper substrate on which the first adhesive layer and the second adhesive layer are disposed.

6. The PoP semiconductor package of claim 1:
wherein the second semiconductor package comprises a die stack encapsulated in a molding compound having a first thermal conductivity;
wherein the thermal structure comprises a second thermal conductivity;
wherein the second thermal conductivity is greater than the first thermal conductivity.

7. The PoP semiconductor package of claim 1 wherein the first semiconductor package comprises a system-on-a-chip (SoC).

8. The PoP semiconductor package of claim 1 wherein the second semiconductor package comprises a stacked memory die encapsulated in a molding compound.

9. The PoP semiconductor package of claim 1 wherein, in operation, a thermal output of the first semiconductor package exceeds a thermal output of the second semiconductor package.

10. The PoP semiconductor package of claim 1 wherein the upper surface of the first semiconductor package comprises a surface having a first area and the lower surface of the second semiconductor package comprises a surface having a second area, the second area less than the first area.

11. The PoP semiconductor package of claim 1, further comprising a plurality of conductive structures to communicably couple the first semiconductor package to the second semiconductor package.

12-25. (canceled)

26. The PoP semiconductor package of claim 1 wherein the first adhesive layer is disposed across an entirety of the first surface of the rigid member.

27. The PoP semiconductor package of claim 26, wherein the second adhesive layer is disposed across an entirety of the second surface of the rigid member.
